(19) United States
(12) Patent Application Publication
(10) Pub. No.: US 2025/0157536 A1
(43) Pub. Date: May 15, 2025

(54) ESTIMATING THE INITIAL STATE OF A RESISTIVE ELEMENT

(71) Applicants: Commissariat à l'Energie Atomique et aux Energies Alternatives, PARIS (FR); Weebit Nano Ltd., HOD HASHARON (IL)

(72) Inventors: Lucas REGANAZ, Grenoble (FR); Gabriel MOLAS, Grenoble (FR)

(21) Appl. No.: 18/938,371

(22) Filed: Nov. 6, 2024

(30) Foreign Application Priority Data
Nov. 10, 2023 (FR) 2312291

(51) Int. Cl. G11C 13/00

(52) U.S. Cl. CPC G11C 13/004; G11C 13/0064; G11C 2013/0054

(57) ABSTRACT

The present disclosure relates to a method for estimating the resistive state to which a cell of a memory is programmed, the method comprising: a) a first measurement, by a measurement circuit coupled to the cell, of a first value representative of the resistance of the cell; b) at least one second measurement of at least one second value representative of the resistance of the cell; c) comparison, by a comparison circuit, of the first and the at least one second values representative of the resistance; and d) based on the comparison, estimate of the resistive state of the cell, the estimate being either of a high resistance state if the at least one second representative value has an increase relative to the first representative value, or of a low resistance state if the at least one second value has a decrease relative to the first representative value.

### FIELD

The present description relates generally to resistive non-volatile memories, and in particular to the estimate of the resistance states to which each resistive element of the memory has initially been programmed.

### BACKGROUND

Volatile resistive memories comprise a plurality of resistive elements. Each resistive element is initially programmed to a High Resistance State (HRS) or a Low Resistance State (LRS).

However, once programmed, a resistive element undergoes relaxation effects, resulting in fluctuations of the resistance to which it was initially programmed. Thus, an element programmed to a high resistance state may see its resistance decrease up to become a low resistance state, and vice versa for an element programmed to a low resistance state.

Although relaxation effects stabilize after a while, fluctuations of resistance still occur.

There is a need to estimate the state to which a resistive element of a resistive non-volatile memory was initially programmed.

### SUMMARY

One embodiment provides a method for estimating the resistive state to which a cell of a non-volatile resistive memory is programmed, the method comprising:
a) a first measurement, by a measurement circuit coupled to the memory cell, of a first value representative of the resistance of the cell, and comparison of the first representative value with a reference interval;
b) if the first measurement is less than the lower limit of the reference interval, the estimation of the resistive state of the cell as being a low resistance state, if the first measurement is greater than the upper limit of the reference interval, the estimation of the resistive state of the cell as being a high resistance state, and if the at least one first measurement is within to the reference interval, at least one second measurement, by the measurement circuit, of at least one second value representative of the resistance of the same memory cell when the cell is in the resistive state, the resistive state to which the cell is programmed not being modified between the at least one first measurement and the at least one second measurement;
c) comparison, by a comparison circuit, of the first and the at least one second value representative of the resistance; and
d) based on the comparison, estimate of the resistive state of the cell, the estimate being either an estimate of a high resistance state if the at least one second representative value has an increase relative to the first representative value of the resistance, or an estimate of a low resistance state if the at least one second representative value has a decrease relative to the first representative value.

According to an embodiment, the comparison circuit is configured to compare the first representative value of the resistance with a reference value based on the at least one second representative value of the resistance, the reference value not being constant and fixed for all memory cells of the resistive memory.

According to an embodiment, the comparison circuit is configured to determine only a relative relationship between the first representative value of the resistance and the at least one second representative value of the resistance, without performing a subtraction operation between the first representative value of the resistance and the at least one second representative value of the resistance.

According to one embodiment, the above method further comprises:
before performing step a), a first application, at a first time, of a current of predefined intensity or of a predefined voltage to the resistive memory cell, the first measurement being performed based on the first application; and
following performing step a), and prior to performing step b), at least one second application, at at least one second time, later than the first time, of the current or of a predefined voltage to the resistive element, the at least one second measurement being performed based on the at least one second application.

According to one embodiment, the above method further comprises, following estimate of the state:
reprogramming the cell to the estimated state.

According to one embodiment, the above method further comprises, following estimate of the state:
storing in a memory, in association with the cell, a value indicating the estimated state.

According to one embodiment, the above method further comprises following measurement of the first representative value, if the first representative value is outside the reference interval, repeating the method from a new implementation of step a).

According to one embodiment, the above method further comprises, prior to the comparison:
converting, by a converter, the first and the at least one second representative values into a first and at least one second digital values;
storing, in association with the cell, the first and the at least one second digital values in a memory.

According to one embodiment, the memory is a shift register.

According to one embodiment, the comparison is performed based on voltage values stored by a first and at least one second capacitors configured to store the first and at least one second representative values respectively.

According to one embodiment, the estimated state is a high resistance state if, upon comparison, it is determined that the first representative value is less than one of the at least one second representative value, and wherein the estimated state is a low resistance state if, upon comparison, it is determined that the first representative value is greater than one of the at least one second representative value.

According to one embodiment, the estimated state is a high resistance state if, during the comparison, it is determined that the first representative value is lower than the average of the at least one second representative value.

According to one embodiment, the at least one second representative value comprises a first second value and a second second value, the second second value being measured at a time later than the second time, and wherein the estimated state is a high resistance state if, upon comparison, it is determined that the average of the differences between the first second and the second second representative values and between the first second and the first representative values is positive, and wherein the estimated state is a low resistance state if, upon comparison, it is determined that the average of the differences between the first second and the second second representative values and between the first second and the first representative values is negative.

According to one embodiment, the second time is at least 3 seconds, and for example at least one minute, away from the first time.

According to one embodiment, the first and at least one second representative resistance values are voltage or current values representative of the cell resistance.

One embodiment provides a circuit comprising a non-volatile resistive memory comprising a cell, programmed to one resistive state of a plurality of states, the circuit further comprising:
a measurement circuit configured to measure a first value representative of the cell resistance when the cell is in the resistive state;
a comparison circuit configured to determine whether the first representative value is within a reference interval and if the first measurement is less than the lower limit of the reference interval, estimate that the resistive state of the cell is a low resistance state, if the first measurement is greater than the upper limit of the reference interval, estimate that the resistive state of the cell is a high resistance state, and,
the measurement circuit being further configured to, if the first representative value is within the reference interval, measure at least one second value representative of the resistance of the same memory cell when the cell is in the resistive state, the resistive state to which the cell is programmed not being modified between the first measurement and the at least one second measurement, and the comparison circuit being further configured to compare the first representative value with the at least one second representative value to estimate the state of the cell, the estimate being an estimate of a high resistance state if the at least one second representative value has an increase relative to the first value representative of the resistance, or of a low resistance state if the at least one second representative value has a decrease relative to the first representative value.

According to one embodiment, the comparison circuit is an analog circuit configured to store the first representative value and the at least one second representative value in an analog form.

According to one embodiment, the comparison circuit is a digital circuit configured to store the first representative value and the at least one second representative value in digital form, for example as binary values.

According to one embodiment, the above circuit further comprises a current source configured to apply a current having a predefined intensity, or a voltage source configured to apply a predefined voltage, to the cell at a first time and then at at least one second time, later than the first time, the measurement of the first representative value being performed based on the application at the first time, and the measurement of the at least one second representative value being performed based on the application at the at least one second time.

According to one embodiment, the non-volatile memory is a filament-type memory, such as a Resistive Random Access Memory (RRAM).

According to one embodiment, the non-volatile memory is a phase-change memory, or an oxide-based resistive memory, or a programmable metallization cell.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a graph illustrating fluctuations of the resistance of resistive elements programmed to high resistance or low resistance states;

FIG. 2A is a graph illustrating fluctuations of the resistance of resistive elements around a reference interval;

FIG. 2B illustrates resistance variations around the reference interval;

FIG. 3 is a graph illustrating the evolution over time of the resistance of resistive elements;

FIG. 4A is a graph illustrating the deviation in fluctuations of resistive elements programmed to a high resistance state;

FIG. 4B is a graph illustrating the deviation in fluctuations of resistive elements programmed to a low resistance state;

FIG. 5 is a graph illustrating the average fluctuations of resistive elements programmed to high or low resistance states;

FIG. 6A is a graph illustrating two measurements;

FIG. 6B is a graph illustrating several measurements; and

FIG. 7 is a block diagram illustrating a circuit according to one embodiment of the present description.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, resistive memory technologies, as well as the reprogramming of resistive elements, are known to those skilled in the art. In particular, the reprogramming of filament memory cells to a high, and/or low, resistance state is known to those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

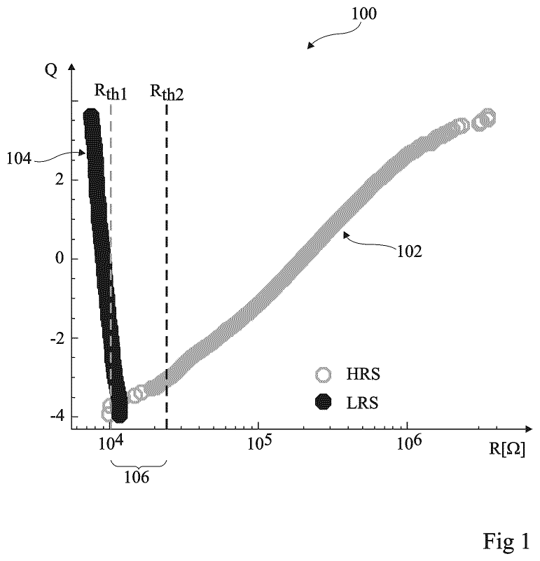

FIG. 1 is a graph 100 illustrating fluctuations of the resistance of resistive elements programmed to high and low resistance states. In particular, curves 102 and 104 have been obtained from experiments. By way of example, the experiments performed measure the resistance value of resistive elements, for example following a measurement of the output voltage of the elements. The resistive elements are, for example, cells in a non-volatile resistive ReRAM (Resistive Random Access Memory). By way of example, the non-volatile memory is a filament memory. In other examples, the non-volatile memory is a Change Phase Memory (PCM), an Oxide Random Access Memory (OxRAM), a programmable metallization cell, and so on.

Curve 102 illustrates the distribution of resistive measurements (R[Ω]) of resistive elements initially programmed to a high resistance state (HRS). In particular, the measurements are performed a period of time after the resistive elements have been programmed. By way of example, measurements were performed 6 seconds after initial programming.

Curve 104 illustrates the distribution of resistance measurements of resistive elements initially programmed to a low resistance state (HRS). More specifically, the measurements are performed a period of time after the resistive elements have been programmed. By way of example, measurements were performed 6 seconds after initial programming.

The y-axis of graph 100 represents the quantiles (Q) for the measurements performed. In particular, the quantiles shown are relative to a normal, theoretical distribution for the measurements performed. By way of example, the resistance value corresponding to the quantile equal to 0 is the median resistance value. Similarly, the set of resistance values located between quantile values −1 and 1 represents 68.27% of the total number of values. In other words, the unit Q is the standard deviation of the normal distribution of resistance values.

Generally speaking, the resistance values of cells programmed to high and low resistance states follow log-normal laws. In addition, the resistances assumed by elements programmed to a high resistance state are more dispersed than the resistances assumed by elements programmed to low resistance states. Indeed, the resistance values of the LRS elements illustrated in FIG. 1 range from 1,000 ohms to around 20,000 ohms, whereas the resistances of the HRS elements range from 10,000 ohms to 10⁷ ohms.

An interval 106 represents a range of resistance values that can be assumed by resistive elements initially programmed to the high resistance state and to the low resistance state. In other words, the reference interval 106 corresponds to the overlap of the distributions of resistance values that can be taken by a memory cell in a high resistance state or in a low resistance state. On the contrary, resistance values below the interval 106 correspond only to resistive elements initially programmed in the low resistance state, and resistance values above the interval 106 correspond only to resistive elements initially programmed in the high resistance state. The interval 106 extends from a resistance value of Rₜₕ₁ ohms to a resistance value of Rₜₕ₂ ohms. By way of example Rₜₕ₁=11,000 and Rₜₕ₂=25,000. More generally, Rₜₕ₁ is a value in the range from 8,000 ohms to 20,000 ohms, and Rₜₕ₂ is a value in the range from 20,000 ohms to 50,000 ohms. The preceding values Rₜₕ₁ and Rₜₕ₂ are given as examples, and may differ, for example, from one type of memory to another.

In addition, following their initial programming, the resistance values of the LRS and HRS elements undergo a relaxation effect and fluctuate. Even once the distributions of the resistances of the HRS and LRS elements have stabilized, the resistance of each cell continues to fluctuate individually.

In the case of filament memories, the relaxation effect comes from the dynamic stabilization of the filament, which modifies cell resistance. Indeed, atoms, such as oxygen atoms, can move and recombine over a period of time, until stabilization is achieved.

Fluctuations before and after stabilization do not alter the distributions of resistance values for each HRS and LRS state. However, when values fluctuate around and within the interval 106, it is difficult to differentiate an HRS from an LRS element.

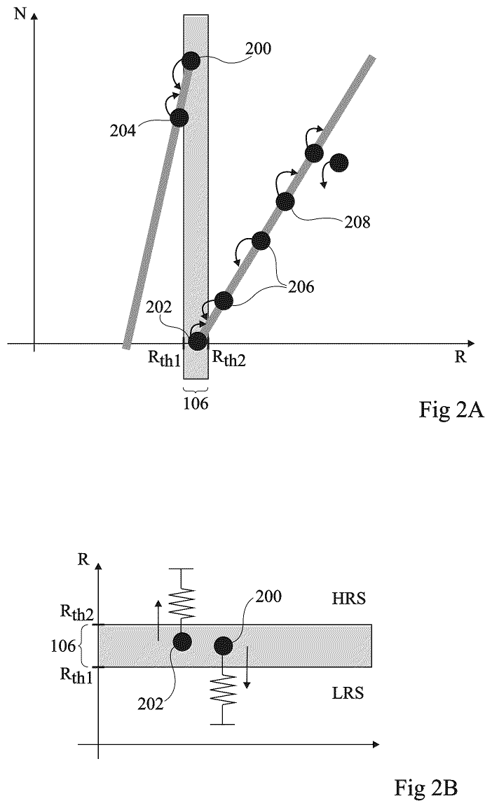

FIG. 2A is a graph illustrating fluctuations of the resistance of resistive elements around interval 106.

FIG. 2B illustrates resistance variations around interval 106.

The y-axis of the graph illustrated in FIG. 2A represents the quantiles, as described in relation to FIG. 1, relative to a theoretical normal distribution for measurements performed. The two inclined segments represent, respectively, the theoretical normal distributions for the LRS and HRS states. By way of example, the x-axis of the graph illustrated in FIG. 2A is in logarithmic scale.

By way of example, a resistance value 200 represents the resistance value of an element initially programmed to an LRS state, and having fluctuated until it is within the reference interval 106. The resistance of this element will then generally decrease, or fall, so as to leave the interval 106. Similarly, a resistance value 202 represents the resistance value of an element initially programmed to an HRS state, and having fluctuated until it is within the reference interval 106. The resistance of this element will then generally expand, or increase, so as to leave the interval 106. Generally speaking, the resistance of an HRS or LRS element, when it enters the interval 106, will tend to go back a value specific to its initial state.

Outside the interval 106, LRS elements, for example with resistance 204, generally increase in resistance. HRS elements, for example with resistance 206, generally decrease in resistance. These increase and decrease outside the interval 106 are trends. Indeed, the resistance of HRS elements will sometimes fluctuate and increase, as is the case for resistance 208, for example.

So, when an HRS or LRS resistive element with its resistance in the interval 106 has its resistance leaving the interval 106, another resistive element programmed to the same state will have its resistance fluctuate and enter the interval 106.

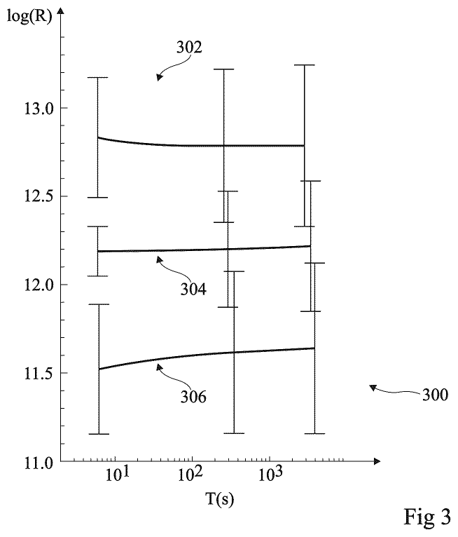

FIG. 3 is a graph 300 illustrating the evolution over time of the resistance of HRS resistive elements.

In particular, graph 300 illustrates the evolution of the logarithm of the resistance value (log(R)) as a function of time (T[s]). Graph 300 comprises curves 302, 304, and 306 dividing the resistance evolution into terciles. In other words, each curve 302, 304, and 306 illustrates the resistance evolution of the same number of resistive elements. Curve 302 illustrates the evolution of the resistances of the upper tercile, i.e. the third of resistive elements with the highest resistance values. Curve 304 illustrates the evolution of the resistances of the middle tercile. Curve 306 illustrates the evolution of the resistances of the lower tercile, i.e. the third of resistive elements with the lowest resistance values.

Upper tercile resistances tend to decrease over time, while middle and lower tercile resistances tend to increase. The tercile averages for the HRS and LRS states tend to move closer together. This moving closer occurs with increasing deviation. Indeed, each element the resistance of which increases in a distribution is replaced with another element the resistance of which decreases.

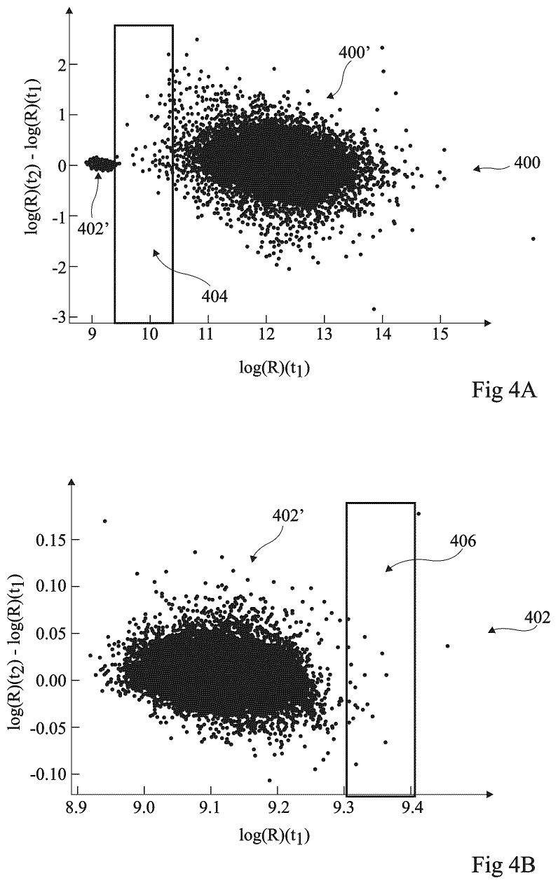

FIG. 4A is a graph 400 illustrating the deviation in fluctuations of resistive elements programmed to a high resistance state.

FIG. 4B is a graph 402 illustrating the deviation in fluctuations of resistive elements programmed to a low resistance state.

In particular, graphs 400 and 402 comprise point clouds 400′ and 402′. Each point of the clouds 400′ and 402′ has as its x-axis coordinate the logarithm of the resistance of a resistive element at a time t₁ log(R)(t₁). By way of example, the time t₁ takes place a few seconds, for example 6 seconds, after the resistive element has been programmed. The y-axis coordinate of each point in the clouds 400 and 402 is the difference between the logarithms of the resistance of the resistive element between a time t₂ and time t₁(log(R)(t₂)−log(R)(t₁)). By way of example, time t₂ is later than time t₁, and takes place several tens of minutes after the element has been programmed, for example, one hour after programming. In particular, cloud 400′ illustrates the time variation in resistance of resistive elements programmed to an HRS state. Cloud 402′ illustrates the time variation in resistance of resistive elements programmed to an LRS state.

A frame 404 shows a negative drift in the time variation in the resistance of resistive elements programmed to an HRS state, illustrating the tendency of HRS element resistances to increase. Similarly, a frame 406 shows a positive drift in the time variation in the resistance of resistive elements programmed to an LRS state, illustrating the tendency of LRS element resistances to decrease. These trends are only significant for elements the resistance of which have values within frames 404 and/or 406.

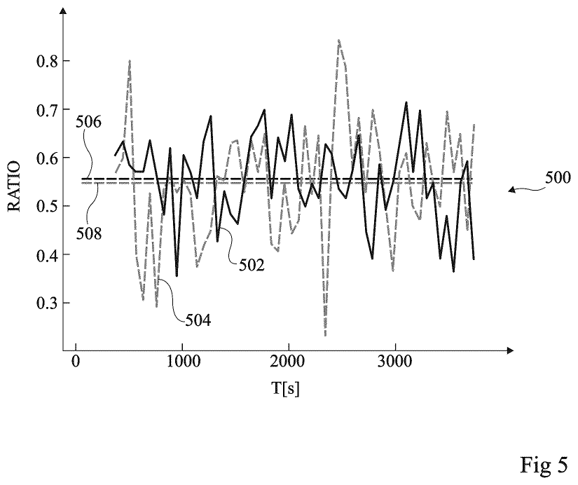

FIG. 5 is a graph 500 illustrating the average fluctuations of resistive elements programmed to high or low resistance states. More specifically, graph 500 comprises a curve 502 and a curve 504. Curves 502 and 504 are respectively obtained by consecutive measurements of the resistance of a plurality of resistive elements HRS and LRS when in the reference interval 106. Curves 502 and 504 respectively illustrate the ratio (RATIO) of resistive elements the resistance value of which has increased, respectively decreased. By way of example, for each time t the increase or decrease is obtained by comparing the resistance value measured at time t and the average of resistance values measured at several times within 2 minutes of the time t.

The constant curves 506 and 508 illustrate respectively the average ratio of HRS elements the resistance of which increases and the average ratio of LRS elements the resistance of which decreases.

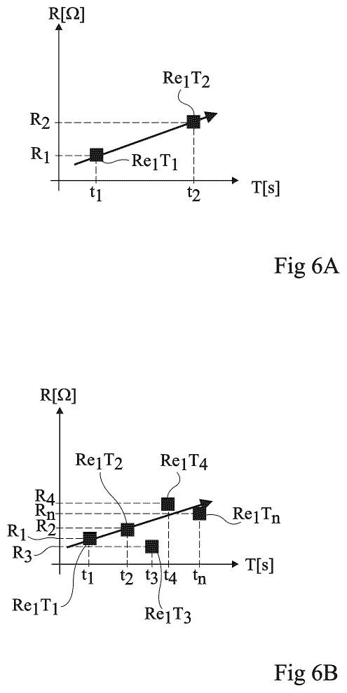

FIG. 6A is a graph illustrating two measurements. By way of example, FIG. 6A illustrates example measurements allowing checking whether a resistance being within the reference interval 106 is tending to increase or decrease.

The example illustrated in FIG. 6A shows a measurement Re₁T₁ performed at a time t₁. By way of example, at time t₁, the resistance of the resistive element under test is equal to R₁ ohms. In particular, due to fluctuations of resistance, the measured resistance is a dynamic value evolving over time. By way of example, the value R₁ is within the reference interval 106. Another measurement Re₁T₂ of the resistance of the resistive element under test is performed, for example, at a time t₂ subsequent to time t₁. By way of example, time t₂ is one or more seconds, for example at least 3 seconds, or one or more minutes, for example at least 1 minute, or at least one hour away from time t₁. In particular, the resistive element is not reprogrammed between two measurements. Thus, the programming state of the resistive element is not modified between two measurements. By way of example, the resistance value at time t₂ is R₂ ohms. In the case R₂ is greater than R₁ as illustrated in FIG. 6A, it is considered that the resistance value has increased. In the opposite case, i.e. if R₁>R₂, it is considered that the resistance value has decreased. In one example, the value R₂ does not be within the reference interval 106.

FIG. 6B is a graph illustrating several measurements Re₁T₁, Re₁T₂, Re₁T₃, Re₁T₄, Re₁Tₙ. By way of example, FIG. 6B illustrates another example of measurements allowing checking whether a resistance being within the reference interval 106 is tending to increase or decrease.

In the example shown in FIG. 6B, n−1, n being an integer, e.g. less than 1,000, other measurements are performed at times later than time t₁. By way of example, the consecutive measurements are performed over a relatively short period of time, for example during a period of time of between 1 ms and 1 s. The number of total measurements that can be performed then depends on the measurement period of time as well as on the time for processing the measurements performed. By way of example, the integer n is between 10 and 1,000. By way of example, the other measurements are performed periodically, e.g. every 6 seconds, every minute, every hour, etc. By way of example, at times t₂, t₄, and tₙ, the measured resistances are respectively equal to R₂, R₄, and Rₙ ohms all greater than the value R₁. However, at a time t₃, the measured resistance is equal to R₃ ohms, less than R₁. Similarly, the value Rₙ is, for example, lower than the value R₄. The sequence of measured resistances is therefore not an increasing sequence. Nevertheless, the average of the values R₂, R₃, R₄, and Rₙ is greater than R₁. In this case, it is considered that the resistance value of the element under test increases. On the contrary, if the average of the values R₂, R₃, R₄, and Rₙ is less than R₁, then the resistance value of the element under test decreases.

According to one embodiment, as soon as the resistance value is within the reference interval 106 at a time t₁, and when it is measured as increasing following one or more other measurements, it is considered that the resistive element under test is an HRS element. On the other hand, if the resistance decreases following one or more other measurements, it is considered that the element is LRS.

Other ways of estimating whether resistance is increasing or decreasing are of course possible. By way of example, the average of differences in resistance values between two consecutive measurements is computed, and if the average is negative, it is considered that the element is LRS, and if the average is positive, it is considered that the element is HRS. In another example, the average of a first number of resistance values, measured for a first number of consecutive times, is compared with the average of a second number of resistance values, measured for a second number of consecutive times, subsequent to the first times.

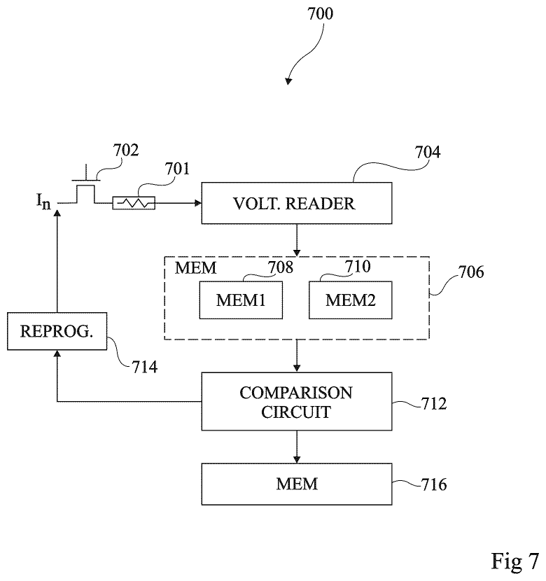

FIG. 7 is a block diagram illustrating a circuit 700 according to one embodiment of the present description.

Circuit 700 comprises a resistive element 701 of a resistive non-volatile memory. The resistive element 701 is supplied with a current Iₙ of predefined intensity, via a transistor 702. In some cases, transistor 702 is used as a current source, in order to control the level of programming current flowing through resistive element 701. In other cases, transistor 702 is an access transistor used to activate or deactivate the programming current, and when activated, the intensity of the programming current is determined, for example, by a current source (not illustrated in FIG. 7), positioned elsewhere in series with resistive element 701, for example at the end of the line of the resistive non-volatile memory matrix. By way of example, element 701 has been initially programmed to an LRS state or to an HRS state. As described in relation to FIGS. 1 to 5, the resistance of element 701 fluctuates with time. The current Iₙ is a current of predefined intensity. By way of example, the current Iₙ, is applied to resistive element 701 at a time t₁.

Alternatively, instead of applying a current of predefined intensity to the resistive element, a predefined voltage is applied to the resistive element.

Circuit 700 further comprises a circuit 704 (VOLT. READER) configured to measure a voltage representative of the resistance of element 701. By way of example, circuit 704 is further configured, for example via a voltage divider, to calculate the value of the resistance of element 701 from the measured voltage. By way of example, circuit 704 comprises an analog-to-digital converter (ADC) configured to convert the measured voltage value into a digital value, and a memory in which the digital value is stored, which is representative of the resistance value of resistive element 701. By way of example, circuit 704 comprises a comparator (not illustrated in the drawing), and is further configured to compare the digital value with the values Rₜₕ₁ and Rₜₕ₂ defining the interval 106. By way of example, when the calculated resistance value does not is within the reference interval 106, and circuit 700 is configured, for example, to reapply current Iₙ or voltage to the resistive element 701.

In one example, circuit 700 further comprises for example a memory 706 (MEM), such as a shift register, configured to receive digital voltage measurements, obtained by circuit 704. By way of example, memory 706 is configured to store a first measurement in a location 708 (MEM1). By way of example, the first measurement is a voltage value corresponding to a resistance being within the reference interval 106. The memory is further configured to store one or more other measurements performed by the circuit 704 in a location 710 (MEM2). By way of example, the measurements stored in location 702 do not all fall within the reference interval 106.

In another example, circuit 704 further comprises an amplifier, such as an Operational Transconductance Amplifier (OTA), configured to supply a current based on the voltage measured at the output of element 701. The memory 706 of the previous example is then replaced with at least two capacitors, each coupled to a switch, and supplied by the current generated by the OTA. The charge of the capacitors is then a representation of the measured resistances of element 701.

Circuit 700 further comprises a comparison circuit (COMPARISON CIRCUIT) 712. By way of example, circuit 712 is configured to determine whether the resistance of element 701 is increasing or decreasing, for example by applying the comparisons described in relation to FIGS. 6A and/or 6B. In one example, comparison circuit 712 is an analog circuit configured to store resistance-representative values, such as current or voltage values, in analog form. In another example, comparison circuit 712 is a digital circuit configured to store resistance-representative values, such as current or voltage values, in digital form. By way of example, the digital format used is a discrete format, such as a binary format.

By way of example, circuit 712 is configured to determine whether the resistance of element 701 is increasing or decreasing by comparing the measured values with several preregistered threshold values. The threshold values are, for example, several values distributed over the interval 106. The comparison circuit 712 is configured, for example, to compare the first resistance measurement with the threshold values in order to determine the closest threshold values between which the first measurement lies. The comparison circuit 712 is then configured to locate the second measurement in the same way. The comparison circuit 712 is then configured to determine whether the resistance of element 701 is increasing or decreasing based on a comparison between the nearest threshold values of the first and second measurements. Thus, in this example, comparison circuit 712 does not perform a direct comparison between resistance measurements. In particular, the comparison circuit 712 is not configured to subtract the two representative resistance values and compare the difference with a threshold value, such as 0. In addition, the nearest threshold values may vary from one memory cell to another. In this example, comparison circuit 712 is configured to compare resistance values with several threshold values.

In another example, the estimate of the state to which element 701 has been programmed is performed by a fully connected neural network. By way of example, the neural network comprises 4 layers. The input layer comprises, for example, a number n of neurons, n corresponding to the number of measurements performed. By way of example, n is a value between 2 and 10. The next two layers comprise, for example, 8n and 2n neurons, respectively. The output layer comprises 1 neuron, and the output indicates whether the estimated state is HRS or LRS. By way of example, the output value is equal to 1 in the case where it is estimated that the state is HRS, in other words, that the resistance tends to increase, and is equal to a value 0 in the case where it is estimated that the state is LRS, in other words, that the resistance tends to decrease.

According to one embodiment, circuit 712 is coupled to a programming circuit 714 (REPROG.). For example, circuit 712 is configured to supply a signal to circuit 714, the signal encoding whether the resistance tends to increase or decrease. In another example, comparison circuit 712 is configured to program the state of a bit in circuit 714. By way of example, the bit is programmed to the state 1 if the resistance tends to increase, and to 0 if the resistance tends to decrease, or vice versa.

Circuit 714 is then configured to reprogram the state of element 701 based on the information supplied by circuit 712. Element 701 is then programmed, by circuit 714, to the HRS state if it has been estimated that the resistance is tending to increase, and to the LRS state if it has been estimated that the resistance is tending to decrease.

According to another embodiment, circuit 712 supplies the information, for example in the form of a signal or by programming a bit, to a memory 716. By way of example, memory 716 is configured to store, in association with an indication of the address of element 701 in non-volatile memory, whether the element is estimated to be HRS or LRS.

In one example, although not shown in FIG. 7, circuit 700 comprises a selection circuit allowing each memory cell of the non-volatile memory to be selectively coupled to circuit elements 704 to 712 and 714.

The following table lists the results obtained when estimates were made by a fully-connected neural network comprising 4 layers of 10, 80, 20 and 1 neurons respectively. Following a measurement in the interval [10,800; 25,000] ohms, 9 further measurements were performed at consecutive 1-minute intervals. A total of 10 measurements were therefore performed, the first being within the interval [10,800; 25,000] ohms, and supplied to the neural network. The neural network is configured to predict, based on the 10 measurements, whether the state of the element under test is HRS or LRS. By way of example, for the experiment, 14,784 memory elements were elements programmed to the HRS state, and 15,061 elements were elements programmed to the LRS state. From these elements, the training and validation of the neural network is on a majority of the elements, for example on 75% of the elements, selected randomly, for example. The remaining elements, corresponding to 25% of elements for example, are used to test the method, in other words to validate the model on data not seen during training. The following table lists the results obtained during model validation, on a total of 7,461 elements not used during network learning and training. A column “basis” shows the number of elements tested, i.e. those entering the interval [10,800; 25,000] ohms. A column “F1-score” shows the F1-scores of the experiment. A column “Recall” includes the recall value of the experiment. A column “Accuracy” comprises the ratio of correctly predicted elements for each class.

TABLE 1

| | Accuracy | recall | F1-score | basis |
|---|---|---|---|---|
| HRS | 0.96% | 0.86 | 0.91 | 3,698 |
| LRS | 0.88% | 0.96 | 0.92 | 3,763 |

Various embodiments and variants have been described. Those skilled in the art will understand that certain features of these embodiments can be combined and other variants will readily occur to those skilled in the art. In particular, this is the case as regards the estimate of the increase or decrease of the resistance value. Similarly, the number of measurements as well as the time interval between two measurements may vary. Selecting the ends defining the reference interval is performed according to the volatile memory and the measurement circuit 704, and is left to those skilled in the art.

Finally, the practical implementation of the embodiments and variants described herein is within the capabilities of those skilled in the art based on the functional description provided hereinabove. In particular, this is the case for implementing elements 704, 706, and 716, which can be analog or digital.

1. A method for estimating the resistive state in which a cell of a non-volatile resistive memory is programmed, the method comprising:
a) a first measurement, by a measurement circuit coupled to the memory cell, of a first value representative of the resistance of the cell when the cell is in the resistive state, and comparison of the first representative value with a reference interval;
b) if the first measurement is less than the lower limit of the reference interval, the estimation of the resistive state of the cell as being a low resistance state, if the first measurement is greater than the upper limit of the reference interval, the estimation of the resistive state of the cell as being a high resistance state, and if the at least one first measurement is within the reference interval, at least one second measurement, by the measurement circuit, of at least one second value representative of the resistance of the same memory cell when the cell is in the resistive state, the resistive state to which the cell is programmed not being modified between the at least one first measurement and the at least one second measurement;
c) comparison, by a comparison circuit, of the first and the at least one second values representative of the resistance; and
d) based on the comparison, estimate of the resistive state of the cell, the estimate being either an estimate of a high resistance state if the at least one second representative value has an increase relative to the first representative value of the resistance, or an estimate of a low resistance state if the at least one second representative value has a decrease relative to the first representative value.

2. The method according to claim 1, wherein the comparison circuit is configured to compare the first representative value of the resistance with a reference value based on the at least one second representative value of the resistance, the reference value not being constant and fixed for all memory cells of the resistive memory.

3. The method according to claim 1, wherein the comparison circuit is configured to determine only a relative relationship between the first representative value of the resistance and the at least one second representative value of the resistance, without performing a subtraction operation between the first representative value of the resistance and the at least one second representative value of the resistance.

4. The method according to claim 1, further comprising:
before performing step a), a first application, at a first time, of a current of predefined intensity or of a predefined voltage to the resistive memory cell, the first measurement being performed based on the first application; and
following performing step a), and prior to performing step b), at least one second application, at at least one second time, later than the first time, of the current or of a predefined voltage to the resistive element, the at least one second measurement being performed based on the at least one second application.

5. The method according to claim 1, further comprising, following estimate of the state:
reprogramming the cell to the estimated state.

6. The method according to claim 1, further comprising, following estimate of the state:
storing in a memory, in association with the cell, a value indicating the estimated state.

7. The method according to claim 1, further comprising, following measurement of the first representative value, if the first representative value is outside the reference interval, repeating the method from a new performing of step a).

8. The method according to claim 1, further comprising, prior to comparison:
converting, by a converter, the first and at least one second representative values into a first and at least one second digital values;
storing, in association with the cell, the first and at least one second digital values in a memory.

9. The method according to claim 1, wherein the comparison is performed based on voltage values stored by a first and at least one second capacitors configured to store respectively the first and at least one second representative values.

10. The method according to claim 1, wherein the estimated state is a high resistance state if, upon comparison, it is determined that the first representative value is lower than one of the at least one second representative value, and wherein the estimated state is a low resistance state if, upon comparison, it is determined that the first representative value is greater than one of the at least one second representative value.

11. The method according to claim 1, wherein the estimated state is a high resistance state if, upon comparison, it is determined that the first representative value is lower than the average of the at least one second representative value.

12. The method according to claim 9, wherein the at least one second representative value comprises a first second value and a second second value, the second second value being measured at a time later than the second time, and wherein the estimated state is a high resistance state if, upon comparison, it is determined that the average of the differences between the first second and second second representative values, and between the first second and first representative values is positive, and wherein the estimated state is a low resistance state if, upon comparison, it is determined that the average of the differences between the first second and second second representative values, and between the first second and first representative values is negative.

13. The method according to claim 1, wherein the second time (t₂) is at least 3 seconds, and for example at least one minute, away from the first time.

14. The method according to claim 1, wherein the first and at least one second representative resistance values are voltage or current values representative of the cell resistance.

15. A circuit comprising a non-volatile resistive memory comprising a cell, programmed to one of a plurality of resistive states, the circuit further comprising:
a measurement circuit configured to measure a first value representative of the cell resistance when the cell is in the resistive state;
a comparison circuit configured to determine whether the first representative value is within a reference interval and if the first measurement is less than the lower limit of the reference interval, estimate that the resistive state of the cell is a low resistance state, if the first measurement is greater than the upper limit of the reference interval, estimate that the resistive state of the cell is a high resistance state, and,
the measurement circuit being further configured to, if the first representative value is within the reference interval, measure at least one second value representative of the resistance of the same memory cell when the cell is in the resistive state, the resistive state to which the cell is programmed not being modified between the first measurement and the at least one second measurement, and the comparison circuit being further configured to compare the first representative value with the at least one second representative value to estimate the state of the cell, the estimate being an estimate of a high resistance state if the at least one second representative value has an increase relative to the first representative value of the resistance, or of a low resistance state if the at least one second representative value has a decrease relative to the first representative value.

16. The circuit according to claim 15, wherein the comparison circuit is an analog circuit configured to store the first representative value and the at least one second representative value in an analog form.

17. The circuit according to claim 15, wherein the comparison circuit is a digital circuit configured to store the first representative value and the at least one second representative value in a digital form, for example as binary values.

18. The circuit according to claim 15, further comprising a current source configured to apply a current of predefined intensity, or a voltage source configured to apply a predefined voltage, to the cell at a first time and then at at least one second time current, later than the first time, the measurement of the first representative value being performed based on the application at the first time, and the measurement of the at least one second representative value being performed based on the application at the at least second time.

19. The circuit according to claim 15, wherein the non-volatile memory is a phase-change memory, or an oxide-based resistive memory, or a programmable metallization cell.
